(19) United States
(12) Patent Application Publication
(10) Pub. No.: US 2014/0239478 A1
(43) Pub. Date: Aug. 28, 2014

(54) SEMICONDUCTOR DEVICE AND METHOD FOR FABRICATING THE SAME

(71) Applicant: SAMSUNG ELECTRONICS CO., LTD., Suwon-si (KR)

(72) Inventors: Ji-Seok HONG, Yongin-si (KR); Sang-Uk HAN, Hwaseong-si (KR); Eun-Kyoung CHOI, Hwaseong-si (KR); Jong-Youn KIM, Seoul (KR); Hae-Jung YU, Seoul (KR); Cha-Jea JO, Bucheon-si (KR)

(73) Assignee: SAMSUNG ELECTRONICS CO., LTD., Suwon-Si (KR)

(21) Appl. No.: 13/803,457

(22) Filed: Mar. 14, 2013

(30) Foreign Application Priority Data
Feb. 25, 2013 (KR) 10-2013-0019996

(51) Int. Cl. H01L 23/538

(52) U.S. Cl. CPC H01L 23/5384
USPC 257/698

(57) ABSTRACT

A semiconductor device includes a first semiconductor chip at least partially overlapping a second semiconductor chip. The first semiconductor chip is coupled to a substrate and has a first width, and the second semiconductor chip has a second width. The device also includes a heat sink coupled to the second semiconductor chip and having a third width different from at least one of the first width or the second width. A package molding section at least partially overlaps a first area of the heat sink and does not overlap a second area of the heat sink which includes a top surface of the heat sink.

### CROSS-REFERENCE TO RELATED APPLICATION

This application claims priority from Korean Patent Application No. 10-2013-0019996 filed on Feb. 25, 2013 in the Korean Intellectual Property Office, and all the benefits accruing therefrom under 35 U.S.C. 119, the contents of which in its entirety are herein incorporated by reference.

### BACKGROUND

1. Field

The present disclosure relates to semiconductor devices.

2. Description of the Related Art

One trend in the electronic industry is to fabricate smaller, lighter, and multifunctional electronic products at reduced cost. In an attempt to satisfy this trend, a multi-chip stacked package technology and a system in package (SIP) technology have been used. In the multi-chip stacked package technology or the SIP technology, through vias are often formed to connect different layers and devices.

Additionally, many times, multiple semiconductor chips are used for a semiconductor package. As a result, heat generation from the semiconductor chips has become an issue. In an attempt to compensate for this effect, various studies are under way which focus on reducing a thickness of a semiconductor package while effectively emitting the heat generated from the semiconductor package.

### SUMMARY

According to one embodiment, a semiconductor device is provided which can reduce a form factor of a semiconductor package by providing a heat sink within the semiconductor package to facilitate heat radiation of the semiconductor package.

According to another embodiment, a method is provided for fabricating the semiconductor device.

According to another embodiment, a semiconductor device includes a mounting substrate, a first semiconductor chip and a second semiconductor chip overlapping and disposed on the mounting substrate, a heat sink disposed on each of the first semiconductor chip and the second semiconductor chip and having the same width as the first semiconductor chip, and a package molding part covering the heat sink and exposing a top surface of the heat sink.

According to another embodiment, a semiconductor device includes a mounting substrate, a first semiconductor chip disposed on the mounting substrate and electrically connected to the first semiconductor chip, the first semiconductor chip having a first width, a heat sink disposed on the first semiconductor chip and having the first width, a package molding part surrounding the heat sink and having an upper surface coplanar with a top surface of the heat sink, and a heat transfer material layer formed to make direct contact with a bottom surface of the heat sink facing the top surface of the heat sink.

### BRIEF DESCRIPTION OF THE DRAWINGS

The above and other features and advantages of example embodiments will become more apparent by describing in detail example embodiments with reference to the attached drawings. The accompanying drawings are intended to depict example embodiments and should not be interpreted to limit the intended scope of the claims. The accompanying drawings are not to be considered as drawn to scale unless explicitly noted.

FIG. 1 shows an embodiment of a semiconductor device.

FIG. 2 shows another embodiment of a semiconductor device

FIGS. 3 to 7 show operations included in one embodiment of a method for fabricating a semiconductor device.

FIGS. 8 and 9 show operations included in another embodiment of a semiconductor device

FIGS. 10 to 14 show operations included in another embodiment of a method for fabricating a semiconductor device

FIG. 15 shows an embodiment of a memory card including semiconductor devices.

FIG. 16 shows an embodiment of an information processing system using semiconductor devices.

FIG. 17 shows an embodiment of an electronic device including semiconductor devices manufactured according to any of the aforementioned method embodiments.

### DETAILED DESCRIPTION OF THE EMBODIMENTS

Detailed example embodiments are disclosed herein. However, specific structural and functional details disclosed herein are merely representative for purposes of describing example embodiments. Example embodiments may, however, be embodied in many alternate forms and should not be construed as limited to only the embodiments set forth herein.

Accordingly, while example embodiments are capable of various modifications and alternative forms, embodiments thereof are shown by way of example in the drawings and will herein be described in detail. It should be understood, however, that there is no intent to limit example embodiments to the particular forms disclosed, but to the contrary, example embodiments are to cover all modifications, equivalents, and alternatives falling within the scope of example embodiments. Like numbers refer to like elements throughout the description of the figures.

It will be understood that, although the terms first, second, etc. may be used herein to describe various elements, these elements should not be limited by these terms. These terms are only used to distinguish one element from another. For example, a first element could be termed a second element, and, similarly, a second element could be termed a first element, without departing from the scope of example embodiments. As used herein, the term “and/or” includes any and all combinations of one or more of the associated listed items.

It will be understood that when an element is referred to as being “connected” or “coupled” to another element, it may be directly connected or coupled to the other element or intervening elements may be present. In contrast, when an element is referred to as being “directly connected” or “directly coupled” to another element, there are no intervening elements present. Other words used to describe the relationship between elements should be interpreted in a like fashion (e.g., “between” versus “directly between”, “adjacent” versus “directly adjacent”, etc.).

In the drawings, it is understood that the thicknesses of layers and regions may be exaggerated for clarity. It will also be understood that when a layer is referred to as being “on” another layer or substrate, it can be directly on the other layer or substrate or intervening layers may also be present. Like reference numerals in the drawings denote like elements, and thus their description will not be repeated. As used herein, the term “and/or” includes any and all combinations of one or more of the associated listed items. Expressions such as “at least one of,” when preceding a list of elements, modify the entire list of elements and do not modify the individual elements of the list.

The terminology used herein is for the purpose of describing particular embodiments only and is not intended to be limiting of example embodiments. As used herein, the singular foul's “a”, “an” and “the” are intended to include the plural forms as well, unless the context clearly indicates otherwise. It will be further understood that the terms “comprises”, “comprising,”, “includes” and/or “including”, when used herein, specify the presence of stated features, integers, steps, operations, elements, and/or components, but do not preclude the presence or addition of one or more other features, integers, steps, operations, elements, components, and/or groups thereof.

It should also be noted that in some alternative implementations, the functions/acts noted may occur out of the order noted in the figures. For example, two figures shown in succession may in fact be executed substantially concurrently or may sometimes be executed in the reverse order, depending upon the functionality/acts involved.

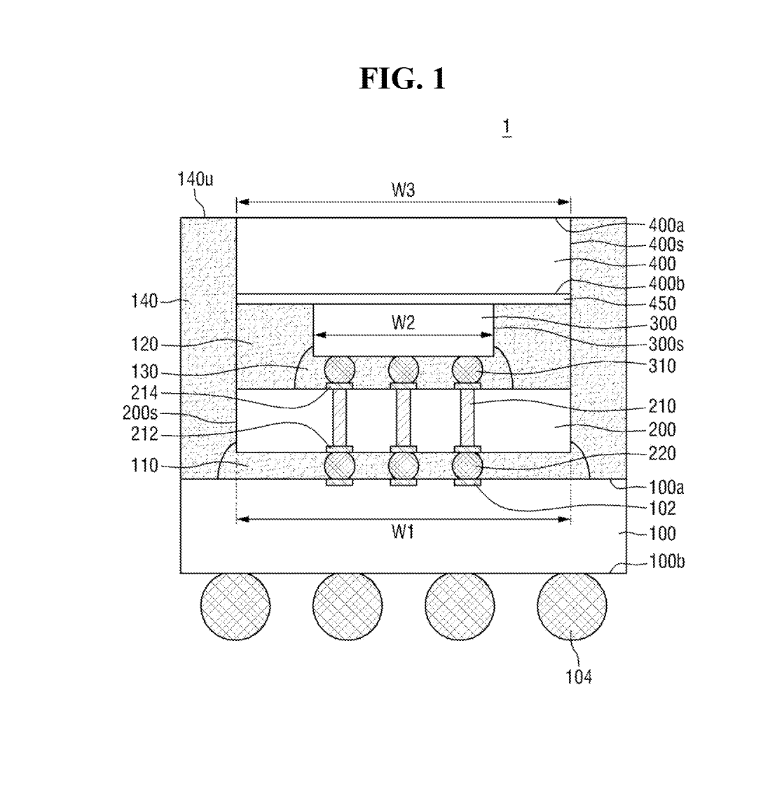

FIG. 1 is a view illustrating an embodiment of a semiconductor device 1 which includes a mounting substrate 100, a lower semiconductor chip 200, an upper semiconductor chip 300, a heat sink 400 and a package molding part 140.

The mounting substrate 100 may be a substrate for packaging, for example, a printed circuit board (PCB) or a ceramic substrate. The mounting substrate 100 may include a top surface 100a and a bottom surface 100b facing each other. One or more external terminals 104 electrically connecting the semiconductor device 1 to an external device may be fowled on a bottom surface 100b of the mounting substrate 100.

Bonding pads 102 may be electrically connected to an external terminal connected to an external device and may supply electrical signals to the lower semiconductor chip 200 and the upper semiconductor chip 300. At least one of the bonding pads 102 may be, for example, a ground pad and may be electrically connected to a ground line in the mounting substrate 100. The bonding pads 102 are positioned, for example, at a central portion of the mounting substrate 100. In other embodiments, the bonding pads may be located at peripheral or other positions of the mounting substrate.

The lower semiconductor chip 200 and the upper semiconductor chip 300 are disposed on the mounting substrate 100. For example, the lower semiconductor chip 200 and the upper semiconductor chip 300 may overlap each other and may be disposed on the mounting substrate 100, or may be sequentially stacked on the mounting substrate 100.

The lower semiconductor chip 200 and the upper semiconductor chip 300 may include, for example, memory chips, logic chips, or the like. When the lower semiconductor chip 200 and/or the upper semiconductor chip 300 are logic chips, they may be designed in various manners in consideration of operations performed by the lower semiconductor chip 200 and/or the upper semiconductor chip 300.

When the lower semiconductor chip 200 and/or the upper semiconductor chip 300 are memory chips, the memory chip may be, for example, a non-volatile memory chip. In detail, the memory chip may be a flash memory chip. In one embodiment, the memory chip may be any one of a NAND flash memory chip or a NOR flash memory chip. However, different types of memory chips may be used in other embodiments. For example, in some embodiments, the memory chip may be a phase-change random access memory (PRAM), a magneto-resistive RAM (MRAM), a resistive RAM (RRAMs), or a combination of these and other memory chips may be included.

The lower semiconductor chip 200 includes one or more through electrodes 210 passing through the lower semiconductor chip 200. In addition, the lower semiconductor chip 200 includes a first lower pad 212 and a first upper pad 214 formed on top and bottom surfaces, respectively. The first lower pad 212 and the first upper pad 214 may be connected to each other by the through electrode 210 passing through the lower semiconductor chip 200. While three through electrodes 210 formed in the lower semiconductor chip 200 are exemplified in FIG. 1, a different number of through electrodes may be included in other embodiment.

The lower semiconductor chip 200 may be electrically connected to the mounting substrate 100 by a lower connection terminal 220 formed on the first lower pad 212. That is to say, the lower connection terminal 220 may electrically connect the first lower pad 212 of the lower semiconductor chip 200 to the bonding pads 102 of the mounting substrate 100. The lower connection terminal 220 is illustrated as a ball-like solder ball, but the lower connection terminal may have other shapes or be of other types in other embodiments. In one embodiment, the lower connection terminal 220 is a solder bump having the solder ball combined with a pillar.

The lower semiconductor chip 200 may be of various types including, for example, a flip chip and the lower connection terminal 220 may be formed on a surface of the lower semiconductor chip 200 having a semiconductor device circuit formed thereon. Also, in the semiconductor device of the present embodiment, the lower semiconductor chip 200 including the through electrode 210 is a single chip.

The upper semiconductor chip 300 may be electrically connected to the lower semiconductor chip 200. That is to say, the upper connection terminal 310 formed on the upper semiconductor chip 300 is connected to the first upper pad 214 of the lower semiconductor chip 200, so that the upper semiconductor chip 300 is electrically connected to the lower semiconductor chip 200.

The upper semiconductor chip 300 may be, for example, a flip chip and the upper connection terminal 310 may be formed on a surface of the upper semiconductor chip 300, on which a semiconductor device circuit is formed. The upper connection terminal 310 is illustrated as a ball-like solder ball, but may be of a different type or may have a different shape in other embodiments. The upper connection terminal 310 may be a solder bump having the solder ball combined with a pillar. In detail, the upper connection terminal 310 may be a micro bump.

In addition, the upper semiconductor chip 300 may be electrically connected to the mounting substrate 100 by through electrode 210 formed in lower semiconductor chip 200. In detail, the upper semiconductor chip 300 may be electrically connected to the mounting substrate 100 through the upper connection terminal 310, the first upper pad 214, the through electrode 210, the first lower pad 212 and the lower connection terminal 220.

In the semiconductor device according to the present embodiment, the upper semiconductor chip 300 electrically connected to the lower semiconductor chip 200 is a single chip.

The heat sink 400 is disposed on the lower semiconductor chip 200 and the upper semiconductor chip 300. In detail, the heat sink 400 is disposed on the upper semiconductor chip 300. The lower semiconductor chip 200, the upper semiconductor chip 300 and the heat sink 400 are sequentially stacked on the mounting substrate 100. The heat sink 400 may be shaped of a planar panel or a thin foil. The heat sink 400 may include a top surface 400a and a bottom surface 400b facing each other, and a sidewall 400s connecting the top surface 400a and the bottom surface 400b.

The heat sink 400 may include a material having high heat conductivity. The heat sink 400 may include, for example, a planar panel or a thin foil. In detail, the heat sink 400 may include, for example, a copper panel, an aluminum panel, a copper foil, an aluminum foil, and combinations thereof.

The heat transfer material layer 450 may be interposed between the heat sink 400 and the upper semiconductor chip 300. That is to say, the heat transfer material layer 450 may be interposed between the bottom surface 400b of the heat sink 400 and the upper semiconductor chip 300. The heat transfer material layer 450 may be formed to make direct contact with the bottom surface 400b of the heat sink 400. The heat transfer material layer 450 may connect the heat sink 400 to the upper semiconductor chip 300. The heat transfer material layer 450 may transfer heat generated from the upper semiconductor chip 300 and the lower semiconductor chip 200 to the heat sink 400.

The heat transfer material layer 450 includes a thermal interface material (TIM) having an adhesive property. The heat transfer material layer 450 may include a curable adhesive material including a metal such as, silver (Ag), or metal oxide based particles such as alumina (Al2O3) contained in an epoxy resin, and a thermal grease including particles made of diamond, aluminum nitride (AlN), alumina (Al2O3), zinc oxide (ZnO) or silver (Ag).

In the semiconductor device according to the present embodiment, the heat transfer material layer 450 is uniformly formed on the bottom surface 400b of the heat sink 400 without voids. However, in other embodiments voids may be included.

Referring to FIG. 1, the lower semiconductor chip 200 has a first width w1, the upper semiconductor chip 300 has a second width w2, and the heat sink 400 has a third width w3. In the semiconductor device according to the present embodiment, the width w1 of the lower semiconductor chip 200 is substantially the same with the width w3 of the heat sink 400. This is because the lower semiconductor chip 200 and the heat sink 400 are formed on the same level, which will be described in more detail with regard to the fabricating method. The expression “the same level” may correspond to the case where elements are formed through the same fabricating process, however in other embodiments the elements may formed at different stages of a fabricating process or using different fabricating processes.

The width w2 of the upper semiconductor chip 300 disposed between the heat sink 400 and the lower semiconductor chip 200 is shown to be smaller than the width w1 of the lower semiconductor chip 200. However, in other embodiments, these widths may be the same or w2 may be greater than w1. The upper semiconductor chip 300 entirely overlaps the lower semiconductor chip 200, or in other embodiments there may only be a partial overlap.

In addition, the width of the heat transfer material layer 450 formed on the bottom surface 400b of the heat sink 400 is shown to be substantially the same with the width w3 of the heat sink 400. Therefore, the width of the heat transfer material layer 450 is substantially the same with the width w1 of the lower semiconductor chip 200. However, the width of the heat transfer material layer 450 is larger than the width w2 of the upper semiconductor chip 300 connected to the heat transfer material layer 450, which is because the heat transfer material layer 450 and the lower semiconductor chip 200 are formed at the same level. (In other embodiments, width w3 may be equal to or less than width w2).

Referring to FIG. 1, a lower underfill part 110 may be formed between the mounting substrate 100 and the lower semiconductor chip 200. The lower underfill part 110 fills a space between the top surface 100a of the mounting surface 100 and the lower semiconductor chip 200 and surrounds the lower connection terminal 220. The lower underfill part 110 may include, for example, an epoxy resin, a silicone hybrid material of two or more materials, or a nonconductive film (NCF).

In the illustrated embodiment, the lower underfill part 110 covers a portion of the sidewall 200s of the lower semiconductor chip 200, but this is not necessary. That is to say, the lower underfill part 110 may be formed only between the bottom surface of the lower semiconductor chip 200 having the first lower pad 212 formed thereon and the top surface 100a of the mounting surface 100. In addition, the lower underfill part 110 may cover the entire surface of the sidewall 200s of the lower semiconductor chip 200.

An upper underfill part 130 may be formed on the upper semiconductor chip 300 and the lower semiconductor chip 200. The upper underfill part 130 fills a space between the lower semiconductor chip 200 and the upper semiconductor chip 300 and surrounds the upper connection terminal 310. The upper underfill part 130 may include, for example, an epoxy resin, a silicone hybrid material of two or more materials, or a nonconductive film (NCF). Like the lower underfill part 110, in the illustrated embodiment, the upper underfill part 130 may cover a portion of the sidewall 300s of the upper semiconductor chip 300, but this is not necessary.

A wafer level molding part 120 may be formed between the heat sink 400 and the upper semiconductor chip 300. Since the heat transfer material layer 450 has the same width as the heat sink 400 and is formed to make direct contact with the bottom surface 400b of the heat sink 400, the wafer level molding part 120 may be formed between the upper semiconductor chip 300 and the heat transfer material layer 450.

In detail, the wafer level molding part 120 surrounds the upper semiconductor chip 300 and the upper underfill part 130. That is to say, the wafer level molding part 120 covers a portion of the sidewall 200s of the upper semiconductor chip 300 and the upper underfill part 130. The wafer level molding part 120 may be formed to make direct contact with the upper semiconductor chip 300, the upper underfill part 130 and the heat transfer material layer 450.

Since the wafer level molding part 120 is formed between the heat sink 400 and the lower semiconductor chip 200, it entirely overlaps the lower semiconductor chip 200. An upper surface of the wafer level molding part 120 and one surface of the upper semiconductor chip 300 making contact with the heat transfer material layer 450 may be positioned on the same plane. That is to say, the upper surface of the wafer level molding part 120 and one surface of the upper semiconductor chip 300 making contact with the heat transfer material layer 450 may be coplanar.

The heat transfer material layer 450 entirely covers the upper semiconductor chip 300 and the wafer level molding part 120. In detail, the width of the heat transfer material layer 450 is substantially equal to a sum of the width w2 of the upper semiconductor chip 300 and the width of the wafer level molding part 120. In addition, the width w3 of the heat sink 400 is substantially equal to a sum of the width w2 of the upper semiconductor chip 300 and the width of the wafer level molding part 120.

In FIG. 1, the wafer level molding part 120 is formed to make contact with one surface of the lower semiconductor chip 200, but this is not necessary. That is, if the upper underfill part 130 entirely covers one surface of the lower semiconductor chip 200 having the first upper pad 214, the wafer level molding part 120 may not contact the one surface of the lower semiconductor chip 200 having the first upper pad 214 but may contact the upper underfill part 130.

The wafer level molding part 120 may include, for example, an epoxy resin, and a silicone hybrid material of two or more materials.

Referring to FIG. 1, in some embodiments, the package molding part 140 may extend to cover a sidewall 400s of the heat sink 400, but this is not necessary. The package molding part 140 may not cover and thus allows a top surface 400a of the heat sink 400 to be exposed.

The package molding part 140 is formed on the top surface 100a of the mounting surface 100 and may cover the lower underfill part 110, sidewall 200s of the lower semiconductor chip 200, the wafer level molding part 120, the heat transfer material layer 450 and the sidewall 400s of the heat sink 400. In detail, the package molding part 140 may be formed to make contact with the lower underfill part 110, the sidewall 200s of the lower semiconductor chip 200, the wafer level molding part 120, the heat transfer material layer 450 and the sidewall 400s of the heat sink 400. The wafer level molding part 120 is disposed between the package molding part 140 and the upper semiconductor chip 300.

The package molding part 140 may include, for example, an epoxy molding compound (EMC), and a silicone hybrid material of two or more materials.

In the semiconductor device according to the embodiment of FIG. 1, the package molding part 140 entirely covers the sidewall 400s of the heat sink 400. That is to say, the sidewall 400s of the heat sink 400 is entirely covered by the package molding part 140. In addition, the top surface 400a of the heat sink 400 are the upper surface 140u of the package molding part 140 are positioned on the same plane. That is to say, the top surface 400a of the heat sink 400 and the upper surface 140u of the package molding part 140 are coplanar.

Also, in FIG. 1, the top surface 400a of the heat sink 400 may be coplanar with the upper surface 140u of the package molding part 140, but this is not necessary. For example, the package molding part 140 may cover a portion of the sidewall 400s of the heat sink 400, so that a portion of the heat sink 400 may protrude from the upper surface 140u of the package molding part 140.

In addition, the package molding part 140 may cover a portion of top surface 400a of the heat sink 400 while entirely covering the sidewall 400s of the heat sink 400. In this case, however, the top surface 400a of the heat sink 400 is exposed.

A boundary surface exists between the wafer level molding part 120 and the package molding part 140. The boundary surface between the wafer level molding part 120 and the package molding part 140 is created due to a curing process completion time difference between the wafer level molding part 120 and the package molding part 140. In detail, if different molding materials are used in the wafer level molding part 120 and the package molding part 140, the boundary surface obviously exists between the wafer level molding part 120 and the package molding part 140.

In some embodiments, the same molding material may be used in the wafer level molding part 120 and the package molding part 140. A boundary surface may therefore exist between the wafer level molding part 120 and the package molding part 140. That is, since the wafer level molding part 120 and the package molding part 140 are subjected to separate curing processes, the boundary surface may exist between the wafer level molding part 120 and the package molding part 140.

In the semiconductor device according to the present embodiment, the upper semiconductor chip 300 makes contact with the heat transfer material layer 450. In alternative embodiments, a portion of the wafer level molding part 120 may be interposed between the upper semiconductor chip 300 and the heat transfer material layer 450. In this case, the wafer level molding part 120 may cover one surface of the upper semiconductor chip 300 facing the heat transfer material layer 450.

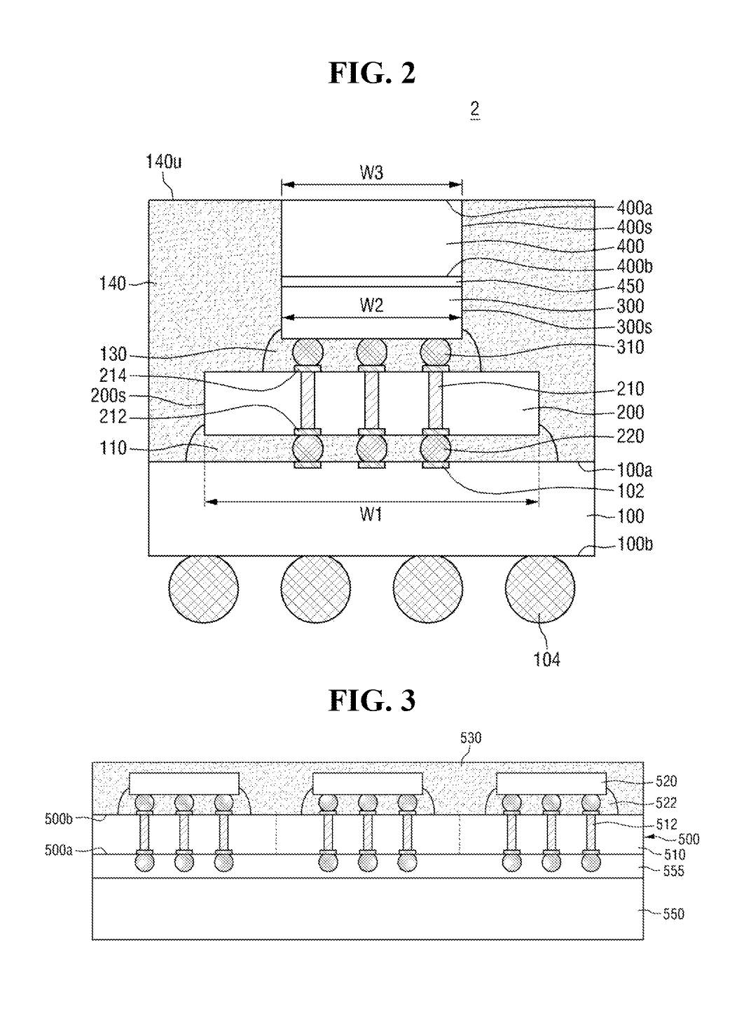

A semiconductor device according to another embodiment is described with reference to FIG. 2. Since the semiconductor device according to the present embodiment is substantially the same as the semiconductor device according to the previous embodiment, except for widths of an upper semiconductor chip, a lower semiconductor chip, and a heat sink, the same components as those of the previous embodiment are denoted by the same reference numerals, and descriptions thereof will be briefly made or will not be made.

Referring to FIG. 2, the semiconductor device 2 includes a mounting substrate 100, a lower semiconductor chip 200, an upper semiconductor chip 300, a heat sink 400 and a package molding part 140. The lower semiconductor chip 200 has a first width w1, the upper semiconductor chip 300 has a second width w2, and the heat sink 400 has a third width w3.

In the semiconductor device according to the present embodiment, the width w2 of the upper semiconductor chip 300 is substantially the same with the width w3 of the heat sink 400. This is because the upper semiconductor chip 300 and the heat sink 400 are formed on the same level, which will be described in more detail.

The width w1 of the lower semiconductor chip 200 disposed between the upper semiconductor chip 300 and the mounting substrate 100 is larger than the width of the upper semiconductor chip 300. The upper semiconductor chip 300 and the heat sink 400 entirely overlap the lower semiconductor chip 200.

In addition, a width of the heat transfer material layer 450 formed on the bottom surface 400b of the heat sink 400 is substantially the same with the width w3 of the heat sink 400. Therefore, the upper semiconductor chip 300, the heat transfer material layer 450 and the heat sink 400, which have the same width, are sequentially stacked on the lower semiconductor chip 200. The width of the heat transfer material layer 450 is the same with the width w2 of the upper semiconductor chip 300 because the heat transfer material layer 450 and the upper semiconductor chip 300 are formed on the same level.

The package molding part 140 may cover a sidewall 400s of the heat sink 400. The package molding part 140 exposes the top surface 400a of the heat sink 400. The package molding part 140 is formed on the top surface 100a of the mounting surface 100 and may cover the lower underfill part 110, the sidewall 200s of the lower semiconductor chip 200, the upper underfill part 130, the sidewall 300s of the upper semiconductor chip 300, the heat transfer material layer 450 and the sidewall 400s of the heat sink 400. In detail, the package molding part 140 may be formed to make contact with the lower underfill part 110, the sidewall 200s of the lower semiconductor chip 200, the upper underfill part 130, the sidewall 300s of the upper semiconductor chip 300, the heat transfer material layer 450 and the sidewall 400s of the heat sink 400.

The package molding part 140 may be formed to make contact with a portion of one surface of the lower semiconductor chip 200 having the first upper pad 214 formed thereon. In other embodiments, if the upper underfill part 130 entirely covers the one surface of the lower semiconductor chip 200 having the first upper pad 214 formed thereon, the package molding part 140 may not make contact with the portion of the one surface of the lower semiconductor chip 200 having the first upper pad 214 formed thereon.

Like in FIG. 1, in FIG. 2, the top surface 400a of the heat sink 400 and the upper surface 140u of the package molding part 140 may be positioned on the same plane. However, the top surface 400a and heat sink 400 may not be coplanar in other embodiments. Hereinafter, a method for fabricating a semiconductor device according to an embodiment of the present invention will be described with reference to FIG. 1 and FIGS. 3 to 7.

FIGS. 3 to 7 illustrate operations included in one embodiment of a method for fabricating a semiconductor device. Referring to FIG. 3, a first semiconductor substrate 500 having a plurality of first semiconductor chips 510 arranged thereon is provided. The provided first semiconductor substrate 500 is attached to a carrier 550.

A plurality of second semiconductor chips 520 are arranged on the first semiconductor substrate 500 and are electrically connected to the first semiconductor chips 510.

Thereafter, a first molding member 522 is formed in a space between each of the first semiconductor substrate 500 and each of the second semiconductor chips 520. After forming the first molding member 522, a wafer level molding member 530 covering the second semiconductor chips 520 is formed on the first semiconductor substrate 500.

In detail, a first semiconductor substrate 500 having a first through electrode 512 is provided. The first semiconductor substrate 500 has a first surface 500a and a second surface 500b facing each other. The first semiconductor substrate 500 includes a plurality of first semiconductor chips 510.

The first semiconductor chips 510 may include a memory element or a logic element. For example, solder balls or solder bumps are formed on the first surface 500a of the first semiconductor substrate 500. In other words, the solder balls or the solder bumps are formed on one surface of the first semiconductor chips 510. The solder balls or the solder bumps are external terminals for inputting or outputting electrical signals to the respective first semiconductor chips 510.

The first semiconductor substrate 500 having the solder balls or the solder bumps is attached to a carrier 550 using a carrier fixing layer 555. The carrier fixing layer 555 is disposed between the first surface 500a of the first semiconductor substrate 500 and the carrier 550. The carrier 550 may be a rigid body, for example, a silicon substrate or a glass substrate, but aspects of the present invention are not limited thereto. The carrier fixing layer 555 includes an adhesive material such as, for example, a glue or resin. In the illustrated embodiment, the carrier fixing layer 555 is a single layer. However, the carrier fixing layer 555 may include multiple layers having different properties.

The first semiconductor substrate 500 including the first through electrode 512 may be formed before or after it is attached to the carrier 550.

In the fabricating method of the semiconductor device according to the present embodiment, the first semiconductor substrate 500 is a single substrate. Alternatively, the first semiconductor substrate 500 may include multiple substrates.

After the first semiconductor substrate 500 is attached to the carrier 550, the second semiconductor chips 520 electrically connected to the first semiconductor chips 510 are mounted on the second surface 500b of the first semiconductor substrate 500. The first semiconductor chips 510 and the second semiconductor chips 520 may be electrically connected to each other by connection terminals formed in the second semiconductor chips 520.

The connection terminals formed in the second semiconductor chips 520 may be solder balls or solder bumps. Since the second semiconductor chips 520 are electrically connected to the first semiconductor chips 510 continuously arranged, a width of each of the second semiconductor chips 520 is smaller than that of each of the first semiconductor chips 510. That is to say, the second semiconductor chips 520 entirely overlap the first semiconductor chips 510.

First molding members 522 between the first semiconductor chips 510 and the second semiconductor chips 520 are formed in the following manner.

First, after the second semiconductor chips 520 are electrically connected to the first semiconductor chips 510, respectively, the first molding members 522 are formed in spaces between the first semiconductor substrate 500 and the second semiconductor chips 520. In other words, the first molding members 522 may be formed by filling the spaces between the first semiconductor chips 510 and the second semiconductor chips 520.

The first molding members 522 may be injected into the spaces between the first semiconductor chips 510 and the second semiconductor chips 520 using, for example, a dispenser. The first molding members 522 may be liquid-type underfill materials, including, for example, an epoxy resin, and a silicone hybrid material of two or more materials. In the illustrated embodiment, the first molding members 522 surround portions of sidewalls of the second semiconductor chips 520, but this is not necessary.

Next, an adhesive film may be attached to one surface of each of the second semiconductor chips 520 having the external terminals formed therein. The adhesive film may be, for example, a nonconductive film (NCF). The second semiconductor chips 520 each having the adhesive film are mounted on the second surface 500b of the first semiconductor substrate 500, which are electrically connected to the first semiconductor chips 510 and the second semiconductor chips 520, and the first molding members 522 are formed by the adhesive film attached to each of the second semiconductor chips 520.

After forming the first molding members 522, the wafer level molding member 530 is formed on the second surface 500b of the first semiconductor substrate 500. The wafer level molding member 530 covers the second semiconductor chips 520. The wafer level molding member 530 may include, for example, an epoxy resin, and a silicone hybrid material of two or more materials. Since the second semiconductor chips 520 are covered by the wafer level molding member 530, they are not exposed.

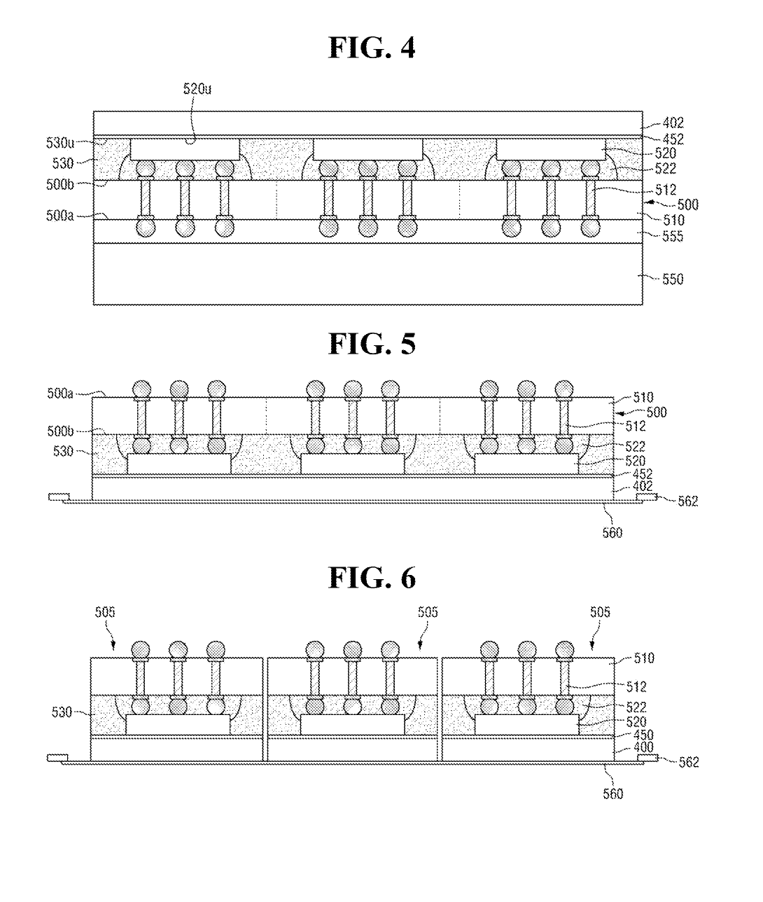

Referring to FIG. 4, a pre-heat transfer material layer 452 and a heat sink substrate 402 are formed on the wafer level molding member 530 and the exposed top surface 520u of the second semiconductor chip 520. That is to say, the heat sink substrate 402 is attached to the first semiconductor substrate 500 having the first semiconductor chips 510 arranged thereon.

In detail, a portion of the wafer level molding member 530 formed on the second surface 500b of the first semiconductor substrate 500 is removed, thereby exposing the top surface 520u of the second semiconductor chip 520. The removing of the portion of the wafer level molding member 530 may be performed by, for example, a planarization process.

As the result of the removing of the portion of the wafer level molding member 530, the top surface 520u of the second semiconductor chip 520 and the top surface 530u of the wafer level molding member 530 may be positioned on the same plane. That is to say, the top surface 520u of the second semiconductor chip 520 and the top surface 530u of the wafer level molding member 530 may be coplanar, but these features may reside in different planes in other embodiments.

After exposing the top surface 520u of the second semiconductor chip 520, the pre-heat transfer material layer 452 is formed on the second surface 500b of the first semiconductor substrate 500. The pre-heat transfer material layer 452 may include a liquid type material or a film, including the material exemplified in the heat transfer material layer 450 shown in FIG. 1.

The pre-heat transfer material layer 452 may be formed by, for example, spin coating or film attachment. When the pre-heat transfer material layer 452 is formed by spin coating, the pre-heat transfer material layer 452 may include a material having viscosity high enough to be uniformly coated on the first semiconductor substrate 500 by rotating the pre-heat transfer material layer 452.

The pre-heat transfer material layer 452 is uniformly formed on the top surface 520u of the second semiconductor chip 520 and the top surface 530u of the wafer level molding member 530.

After forming the pre-heat transfer material layer 452, the heat sink substrate 402 is disposed on the pre-heat transfer material layer 452. In detail, the heat sink substrate 402 may be disposed on the second semiconductor chips 520. The heat sink substrate 402 may include the substrates exemplified in the heat sink 400 shown in FIG. 1.

After the heat sink substrate 402 is disposed on the second semiconductor chips 520, the pre-heat transfer material layer 452 is thermally treated, thereby attaching the heat sink substrate 402 to the second surface 500b of the first semiconductor substrate 500. Since the pre-heat transfer material layer 452 has an adhesive property, the pre-heat transfer material layer 452 cured by the thermal process may fix the heat sink substrate 402 to the first semiconductor substrate 500.

In the fabricating method of the semiconductor device according to the present embodiment, the top surface 520u of the second semiconductor chip 520 is exposed by removing a portion of the wafer level molding member 530,. In other embodiment, the portion of the wafer level molding member 530 is removed, but the top surface 520u of the second semiconductor chip 520 may not be exposed. Therefore, the wafer level molding member 530 may remain on the top surface 520u of the second semiconductor chip 520.

Referring to FIG. 5, the first semiconductor substrate 500 having the heat sink substrate 402 attached thereto is adhered to a wafer ring 562 using a tape 560. In addition, the carrier 550 having the first surface 500a of the first semiconductor substrate 500 attached thereto is removed.

In detail, the first semiconductor substrate 500 having the heat sink substrate 402 attached thereto is adhered to the wafer ring 562 using the tape 560. That is to say, the heat sink substrate 402 having the attached to the second surface 500b of the first semiconductor substrate 500 is attached to the tape 560. The tape 560 may be, for example, a die attach film (DAF).

After the heat sink substrate 402 is attached to the tape 560, the carrier 550 attached to the first surface 500a of the first semiconductor substrate 500 is detached from the first surface 500a of the first semiconductor substrate. The carrier 550 may be attached from the first semiconductor substrate 500 by removing the carrier fixing layer 555 between the first surface 500a of the first semiconductor substrate 500 and the carrier 550.

The removing of the carrier fixing layer 555 may be performed by, for example, one of a thermal sliding method, a laser irradiation method, and a chemical removal method, or a physical removal method. If a residue of the carrier fixing layer 555 remains on the first surface 500a of the first semiconductor substrate 500 even after removing the carrier 550, the residue of the carrier fixing layer 555 may be chemically removed. As the carrier 550 is separated, the first surface 500a of the first semiconductor substrate 500 is exposed.

Referring to FIG. 6, the first semiconductor substrate 500 adhered to the tape 560 is cut by a dicing process. In detail, the first semiconductor substrate 500 and the heat sink substrate 402 are cut into sizes of the first semiconductor chips 510. In such a manner, first semiconductor dies 505 each having the first semiconductor chips 510, the second semiconductor chips 520, the heat transfer material layer 450 and the heat sink 400 sequentially stacked thereon are formed. After performing the dicing process for forming the first semiconductor dies 505, a space between the respective first semiconductor dies 505 can be increased by extending the tape 560.

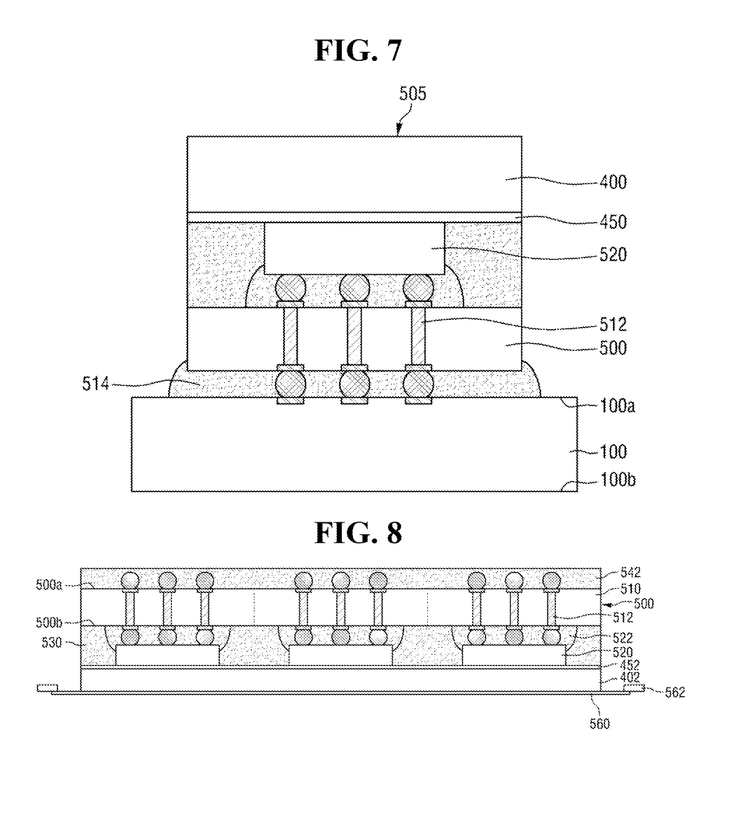

Referring to FIG. 7, the first semiconductor dies 505 are mounted on the mounting substrate 100. That is to say, the first semiconductor chips 510 having the first semiconductor dies 505 are electrically connected to the mounting substrate 100. In addition, the first through electrode 512 included in the first semiconductor chips 510 electrically connects the second semiconductor chips 520 to the mounting substrate 100.

After the first semiconductor dies 505 are mounted on the mounting substrate 100, a second molding member 514 is formed in the space between the first semiconductor chips 510 and the mounting substrate 100. The second molding member 514 may be injected into the space between the first semiconductor chips 510 and the mounting substrate 100 using, for example, a dispenser. The second molding member 514 may be a liquid-type underfill member, including, for example, an epoxy resin, and a silicone hybrid material of two or more materials. The second molding member 514 may fix the first semiconductor dies 505 electrically connected to the mounting substrate 100 to the mounting substrate 100 by curing the second molding member 514.

Referring to FIG. 1, after forming a package molding part 140 on side surfaces of the first semiconductor dies 505, the external terminal 104 is formed on the bottom surface 100b of the mounting substrate 100.

A method for fabricating a semiconductor device according to another embodiment will now be described with reference to FIGS. 1, 3 to 5 and 7 to 9. This embodiment is substantially the same as the previous embodiment, except that an adhesive layer is further formed after removing a carrier. Thus, substantially the same functional components are denoted by the same reference numerals, and descriptions thereof will be briefly made or will not be made.

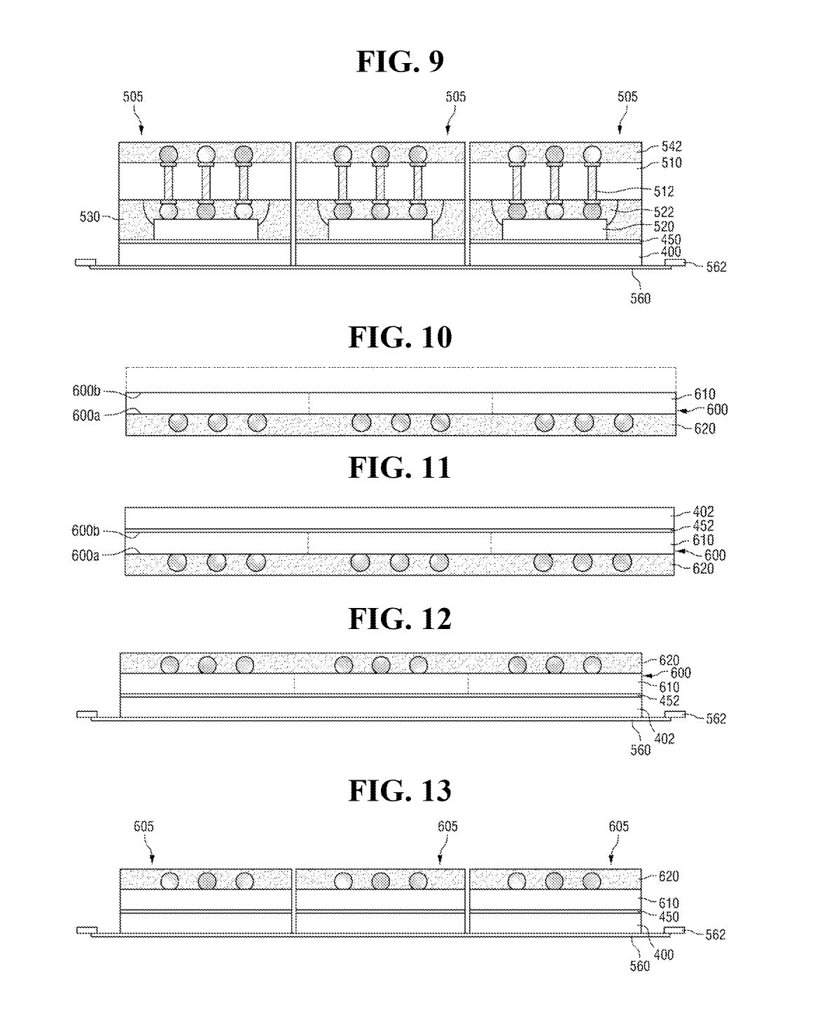

FIGS. 8 and 9 illustrate operations included in another embodiment of a method for fabricating a semiconductor device. Referring to FIG. 8, a pre-adhesion layer 542 is formed on the first surface 500a of the first semiconductor substrate 500 exposed by separating the carrier 550. The pre-adhesion layer 542 may be, for example, a nonconductive film (NCF).

Referring to FIG. 9, the first semiconductor substrate 500 adhered to the tape 560 is cut by a dicing process. In detail, the pre-adhesion layer 542, the first semiconductor substrate 500 and the heat sink substrate 402 are cut into sizes of the first semiconductor chips 510. In such a manner, first semiconductor dies 505 each having first semiconductor chips 510, second semiconductor chips 520, a heat transfer material layer 450 and a heat sink 400 sequentially stacked thereon are formed. After performing the dicing process for forming the first semiconductor dies 505, a space between the respective first semiconductor dies 505 can be increased by extending a tape 560.

Referring to FIG. 7, the adhesion layer 540 may correspond to a second molding member 514 formed in the space between the first semiconductor dies 505 and a mounting substrate 100 when the first semiconductor dies 505 are mounted on the mounting substrate 100. In addition, like the second molding member 514, the adhesion layer 540 may function to fix the first semiconductor dies 505 to the mounting substrate 100.

A method for fabricating a semiconductor device according to still another embodiment will now be described with reference to FIGS. 2 and 10 to 14.

FIGS. 10 to 14 illustrate operations included in another embodiment of a method for fabricating a semiconductor device. Referring to FIG. 10, a second semiconductor substrate 600 having a plurality of third semiconductor chips 610 arranged thereon is provided. After an adhesive layer 620 is attached to one surface of the provided second semiconductor substrate 600, a thickness of the second semiconductor substrate 600 is reduced by polishing the other surface of the second semiconductor substrate 600 without the adhesive layer 620 attached thereto.

In detail, the second semiconductor substrate 600 has a first surface 600a and a second surface 600b facing each other. The second semiconductor substrate 600 includes the plurality of third semiconductor chips 610 arranged thereon. The third semiconductor chips 610 may include, for example, memory devices or logic devices. Solder balls or solder bumps are formed on surface of each of the third semiconductor chips 610, that is, the first surface 600a of the second semiconductor substrate 600.

The adhesive layer 620 is attached to the first surface 600a of the second semiconductor substrate 600 having the solder balls or solder bumps formed thereon. The solder balls or solder bumps formed on the first surface 600a of the second semiconductor substrate 600 may be covered by the adhesive layer 620. The adhesive layer 620 may be, for example, a nonconductive film (NCF).

After the adhesive layer 620 is attached to the first surface 600a of the second semiconductor substrate 600, a thickness of the second semiconductor substrate 600 is reduced by lapping the second surface 600b of the semiconductor substrate 600. The adhesive layer 620 may function as a supporting member of the thickness-reduced second semiconductor substrate 600.

Referring to FIG. 11, a pre-heat transfer material layer 452 and a heat sink substrate 402 are formed on the second surface 600b of the semiconductor substrate 600. That is, the heat sink substrate 402 having the third semiconductor chips 610 arranged thereon is attached to the second semiconductor substrate 600.

In detail, the pre-heat transfer material layer 452 is formed on the second surface 600b of the semiconductor substrate 600. The pre-heat transfer material layer 452 may be formed by, for example, spin coating or film attachment. The pre-heat transfer material layer 452 is uniformly formed on the second surface 600b of the semiconductor substrate 600. After forming the pre-heat transfer material layer 452, a heat sink substrate 402 is disposed on the pre-heat transfer material layer 452. Thereafter, the heat sink substrate 402 is attached to the second surface 600b of the semiconductor substrate 600 by thermally processing the pre-heat transfer material layer 452.

Referring to FIG. 12, the second semiconductor substrate 600 having the heat sink substrate 402 attached thereto is adhered to a wafer ring 562 using a tape 560. The heat sink substrate 402 attached to the second surface 600b of the semiconductor substrate 600 is attached to the tape 560 fixed to the wafer ring 562. The tape 560 may be, for example, a die attach film (DAF).

Referring to FIG. 13, the second semiconductor substrate 600 adhered to the tape 560 is cut by a dicing process. In detail, the second semiconductor substrate 600, the adhesive layer 620 and the heat sink substrate 402 are cut into sizes of the third semiconductor chips 610. In such a manner, second semiconductor dies 605 each having the adhesive layer 620, the third semiconductor chips 610, a heat transfer material layer 450 and the heat sink 400 sequentially stacked thereon are formed. After performing the dicing process for forming the second semiconductor dies 605, a space between the respective second semiconductor dies 605 can be increased by extending the tape 560.

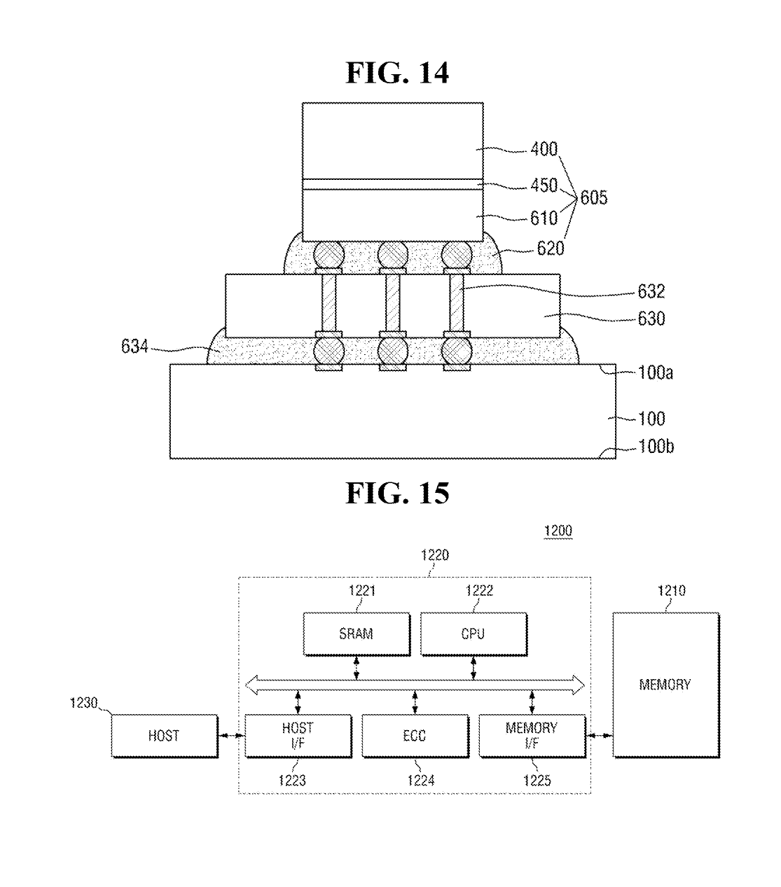

Referring to FIG. 14, the second semiconductor dies 605 are mounted on the mounting substrate 100. The mounting substrate 100 further includes a fourth semiconductor chip 630 electrically connected to the top surface 100a of the mounting surface 100. That is to say, the second semiconductor dies 605 are electrically connected to the mounting substrate 100 by means of the fourth semiconductor chip 630.

The fourth semiconductor chip 630 includes a second through electrode 632. Since the fourth semiconductor chip 630 are interposed between the second semiconductor dies 605 and the mounting substrate 100, the second through electrode 632 may electrically connect the third semiconductor chips 610 to the mounting substrate 100.

In the fabricating method of the semiconductor device according to the present embodiment, the fourth semiconductor chip 630 is a single chip. However, the fourth semiconductor chip 630 may include multiple chips.

The fourth semiconductor chip 630 may be fixed to the mounting substrate 100 by a third molding member 634 third molding member 634 injected into a space between the top surface 100a of the mounting surface 100 and the fourth semiconductor chip 630. The second semiconductor dies 605 may be fixedly attached to the fourth semiconductor chip 630 ad the mounting substrate 100 by the adhesive layer 620 included in the second semiconductor dies 605.

Referring to FIG. 2, after a package molding part 140 covering side surfaces of the second semiconductor dies 605 and the fourth semiconductor chip 630 is formed, an external terminal 104 is formed on the bottom surface 100b of the mounting substrate 100.

FIG. 15 is a block diagram of an embodiment of a memory card including semiconductor devices. Referring to FIG. 15, the memory 1210 including semiconductor devices according to any of the aforementioned embodiments may be employed to the memory card 1200.

The memory card 1200 may include a memory controller 1220 controlling data exchange between a host 1230 and the memory 1210. A static random access memory (SRAM) 1221 may be used as an operating memory of the CPU 1222. A host interface (I/F) 1223 may includes a protocol allowing the host 1230 to access the memory card 1200 for exchanging data. An error correction code (ECC) 1224 may be used to detect an error of data read from the memory 1210 and to correct the detected error. The memory I/F 1225 may interface with the memory 1210. The CPU 1222 may perform the overall operation associated with data exchange of the memory controller 1220.

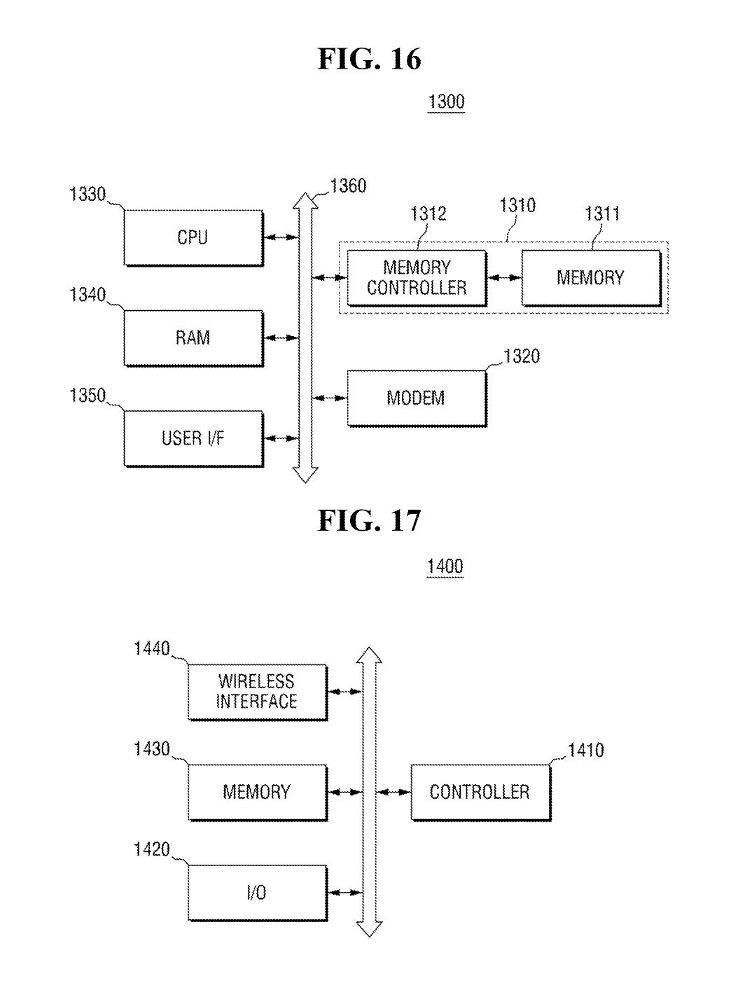

FIG. 16 is a block diagram of an embodiment of an information processing system using semiconductor devices. Referring to FIG. 16, the information processing system 1300 may include a memory system 1310 including semiconductor devices according to any of the aforementioned embodiments.

The information processing system 1300 may include a memory system 1310, a modem 1320, a central processing unit (CPU) 1330, a random access memory (RAM) 1340 and a user interface (I/F) 1350, which are electrically connected to a system bus 1360. The memory system 1310 may include a memory 1311 and a memory controller 1312 and may have substantially the same configuration as the memory card 1200 shown in FIG. 9. The data processed by the CPU 1330 or externally received data may be stored in the memory system 1310. The information processing system 1300 may be applied to a memory card, a solid state disk (SSD), a camera image sensor and other various chip sets. For example, the memory system 1310 may be configured to employ the SSD. In this case, the information processing system 1300 can stably and reliably process massive data.

FIG. 17 is a block diagram of an embodiment of an electronic device including semiconductor devices. Referring to FIG. 17, the electronic device 1400 may include semiconductor devices manufactured according to any of the aforementioned embodiments. The electronic device 1400 may be used in various devices including wireless communication devices, for example, a personal digital assistant (FDA), a notebook computer, a portable computer, a web tablet, a mobile phone, a wireless phone, and/or a digital music system, or wireless information transmitting/receiving systems.

The electronic device 1400 may include a controller 1410, an input/output device (I/O) 1420, a memory 1430, and a wireless interface 1440. Here, the memory 1430 may include semiconductor devices manufactured according to any of the aforementioned embodiments. The controller 1410 may include, for example, at least one microprocessor, a digital signal processor, and a processor device performing similar operations to the above processors. The memory 1430 may be used to store commands (or user data) processed by the controller 1410. The wireless interface 1440 may be used to transmit or receive data through a wireless data network. The wireless interface 1440 may include an antenna and/or a wireless transceiver.

The electronic device 1400 may use third generation communication system protocols such as CDMA (Code Division Multiple Access), GSM (Global System for Mobile communication), NADC (North American Digital Cellular), E-TDMA (Enhanced-Time Division Multiple Access), WCDMA (Wideband Code Division Multiple Access), and CDMA2000.

Example embodiments having thus been described, it will be obvious that the same may be varied in many ways. Such variations are not to be regarded as a departure from the intended spirit and scope of example embodiments, and all such modifications as would be obvious to one skilled in the art are intended to be included within the scope of the following claims.

What is claimed is:

1. A semiconductor device comprising:
a substrate;
a first semiconductor chip at least partially overlapping a second semiconductor chip, the first semiconductor chip coupled to the substrate and having a first width, and the second semiconductor chip having a second width;
a heat sink coupled to the second semiconductor chip and having a third width different from at least one of the first width or the second width; and
a package molding section at least partially overlapping a first area of the heat sink and not overlapping a second area of the heat sink, the second area including a top surface of the heat sink.

2. The semiconductor device of claim 1, wherein the first semiconductor chip and the second semiconductor chip are sequentially stacked on the substrate.

3. The semiconductor device of claim 1, wherein
the first semiconductor chip includes a through electrode, and
the second semiconductor chip is electrically connected to the substrate by the through electrode.

4. The semiconductor device of claim 1, further comprising:
a wafer level molding section interposed between the heat sink and the first semiconductor chip, the wafer level molding section at least partially around the second semiconductor chip.

5. The semiconductor device of claim 4, wherein
the wafer level molding section is disposed between the package molding section and the second semiconductor chip, and
a sum of the second width of the second semiconductor chip and a width of portions of the wafer level molding section around the second semiconductor chip is substantially equal to the third width of the heat sink.

6 The semiconductor device of claim 1, further comprising:
a heat transfer material layer in direct contact with a bottom surface of the heat sink facing a top surface of the heat sink, the heat transfer material layer connecting the heat sink to the second semiconductor chip and having substantially a same width as the first semiconductor chip.

7. The semiconductor device of claim 1, wherein the second semiconductor chip entirely overlaps the first semiconductor chip.

8. The semiconductor device of claim 1, wherein the second semiconductor chip and the first semiconductor chip are sequentially stacked on the substrate.

9. The semiconductor device of claim 8, wherein
the second semiconductor chip includes a through electrode, and
the first semiconductor chip is electrically connected to the substrate by the through electrode.

10. The semiconductor device of claim 8, further comprising
a heat transfer material layer between the heat sink and the first semiconductor chip, the package molding section in direct contact with at least a portion of sidewalls of the first semiconductor chip, sidewalls of the heat sink, and the heat transfer material layer.

11. The semiconductor device of claim 1, wherein the top surface the heat sink and an upper surface of the package molding section are substantially coplanar.

12. The semiconductor device of claim 1, wherein at least a portion of the package molding section extends between the first and second semiconductor chips.

13. The semiconductor device of claim 1, wherein the first width is different from the second width.

14. The semiconductor device of claim 1, wherein
the first width is substantially equal to the third width, and
the first and third widths are different from the second width.

15. The semiconductor device of claim 1, wherein
the second width is substantially equal to the third width, and
the first width is greater than the second width and the third width.

16. A semiconductor device comprising:
a substrate;
a first semiconductor chip coupled to the substrate and electrically connected to the first semiconductor chip, the first semiconductor chip having a first width;
a heat sink coupled to the first semiconductor chip and having substantially the first width;
a package molding section at least partially around the heat sink and having an upper surface that is substantially coplanar with a top surface of the heat sink; and
a heat transfer material layer in direct contact with a bottom surface of the heat sink facing the top surface of the heat sink.

17. The semiconductor device of claim 16, further comprising:
a second semiconductor chip between the first semiconductor chip and the heat sink and having a second width smaller than the first width.

18. The semiconductor device of claim 17, wherein
the second semiconductor chip is electrically connected to the substrate by a through electrode in the first semiconductor chip, and
the second semiconductor chip is connected to the heat sink by the heat transfer material layer.

19. The semiconductor device of claim 16, wherein the heat transfer material layer has substantially the first width.

20. The semiconductor device of claim 16, further comprising
a second semiconductor chip between the first semiconductor chip and the substrate and electrically connected to the substrate, the second semiconductor chip including a through electrode and the first semiconductor chip is electrically connected to the substrate by the through electrode.
